(19) United States
(12) Patent Application Publication
(10) Pub. No.: US 2013/0321726 A1
(43) Pub. Date: Dec. 5, 2013

(54) FLAT PANEL DISPLAY

(71) Applicants: Jae-Yong Lee, Yongin-si (KR); Won-Kyu Kwak, Yongin-si (KR)

(72) Inventors: Jae-Yong Lee, Yongin-si (KR); Won-Kyu Kwak, Yongin-si (KR)

(21) Appl. No.: 13/619,252

(22) Filed: Sep. 14, 2012

(30) Foreign Application Priority Data
May 29, 2012 (KR) 10-2012-0056806

(51) Int. Cl. G02F 1/1343; H01L 27/32

(52) U.S. Cl. 349/38; 257/88; 257/E27.119; 257/40

(57) ABSTRACT

A flat panel display (FPD) includes a substrate, a plurality of pixel units on the substrate, each of the pixel units including a display element, a thin film transistor (TFT) electrically coupled to the display element, and a capacitor electrically coupled to the TFT and including electrodes, wherein the electrodes of the capacitor of a first pixel unit of the pixel units are extended to an adjacent pixel unit of the pixel units.

### CROSS-REFERENCE TO RELATED APPLICATION

This application claims priority to and the benefit of Korean Patent Application No. 10-2012-0056806, filed on May 29, 2012, in the Korean Intellectual Property Office, the entire content of which is incorporated herein by reference.

### BACKGROUND

1. Field

Embodiments of the present invention relate to a flat panel display.

2. Description of the Related Art

A flat panel display (FPD), such as a liquid crystal display (LCD) and an organic light emitting display (OLED), includes a plurality of pixels that are driven by a pixel circuit, which includes a thin film transistor (TFT) for driving the pixels and a capacitor coupled to the TFT to maintain a signal.

Since the pixel circuit is manufactured by a process of manufacturing a semiconductor device in processes of manufacturing the FPD, electrical characteristics of the TFT and the capacitor may be easily changed by a process method or a process condition, resulting in a picture quality of the FPD that may be non-uniform.

### SUMMARY

Accordingly, embodiments of the present invention provide a flat panel display (FPD) in which the electrical characteristic of a capacitor are substantially uniform.

Embodiments of the present invention also provide an FPD with substantially uniform picture quality.

In order to achieve the foregoing and/or other aspects of embodiments of the present invention, there is provided a flat panel display (FPD) including a substrate, a plurality of pixel units on the substrate, each of the pixel units including a display element, a thin film transistor (TFT) electrically coupled to the display element, and a capacitor electrically coupled to the TFT and including electrodes, wherein the electrodes of the capacitor of a first pixel unit of the pixel units are extended to an adjacent pixel unit of the pixel units.

The electrodes of the capacitor of the first pixel unit may overlap electrodes of the capacitor of the adjacent pixel unit.

The electrodes of the capacitor may include a concave first part, and a second part extending from the first part, and the second part of the capacitor of the first pixel unit may be at least partially surrounded by the first part of the capacitor of the adjacent pixel unit.

The electrodes of the capacitor may include a lower electrode and an upper electrode, and at least one of the lower electrode or the upper electrode may include a polysilicon layer.

The TFT may include an activation layer at a same plane as one of the lower electrode and the upper electrode of the capacitor.

The polysilicon layer may be crystallized by a laser beam.

The FPD may further include protrusions arranged at the polysilicon layer.

The protrusions may include protrusions in the electrodes of the capacitor, and the protrusions in the electrodes of the capacitor of the first pixel unit may align with the protrusions in the electrodes of the capacitor of the adjacent pixel unit.

The display element may include a liquid crystal (LC) cell.

The display element may include an organic light emitting diode (OLED).

The electrodes of the capacitor may include a lower electrode and an upper electrode, and at least one of the lower electrode or the upper electrode of the first pixel unit may be extended to the adjacent pixel unit.

At least one of the lower electrode or the upper electrode may include a polysilicon layer.

In an embodiment of the present invention, the electrodes of the capacitor formed in a pixel unit are extended to another adjacent pixel unit, and the extended electrodes of the capacitor overlap the electrodes of the capacitor of the adjacent pixel unit. In addition, a plurality of protrusions are arranged on the surface of one electrode formed of a polysilicon layer between the two electrodes of the capacitor, and the number of protrusions arranged in the electrodes of the capacitor of each of the pixels is uniform or is included in a uniform range.

When the number of protrusions formed in the electrodes of the capacitors is uniform, since the distances between the lower electrodes and the upper electrodes of the capacitors may be equalized, the capacitances of all of the capacitors may be almost the same. Therefore, it is possible to reduce or prevent spots from being generated due to a difference in the capacitances.

### BRIEF DESCRIPTION OF THE DRAWINGS

The accompanying drawings, together with the specification, illustrate exemplary embodiments of the present invention, and, together with the description, serve to explain aspects of embodiments of the present invention.

FIG. 1 is a schematic plan view illustrating a flat display panel (FPD) according to embodiments of the present invention;

FIGS. 2 and 3 are circuit diagrams illustrating embodiments of the pixel unit P of the embodiments shown in FIG. 1;

FIGS. 4 and 5 are layout diagrams illustrating embodiments of the pixel unit P of the embodiments shown in FIG. 1;

FIG. 6 is a sectional view illustrating an embodiment of the pixel unit P of the embodiments shown in FIG. 1;

FIG. 7 is a plan view illustrating an electrode of a capacitor with protrusions formed; and

FIG. 8 is a plan view of a capacitor illustrating an embodiment of the present invention.

### DETAILED DESCRIPTION

Hereinafter, certain exemplary embodiments according to the present invention will be described with reference to the accompanying drawings. Here, when a first element is described as being coupled to a second element, the first element may be directly coupled to the second element or may be indirectly coupled to the second element via one or more other elements. Further, some of the elements that are not essential to the complete understanding of the invention are omitted for clarity. Also, like reference numerals refer to like elements throughout.

Hereinafter, embodiments of the present invention will be described in detail with reference to the accompanying drawings. The following embodiments are provided so that the present invention is fully understood to those skilled in the art, and may vary in various forms. The scope of the present invention is not limited to the following embodiments.

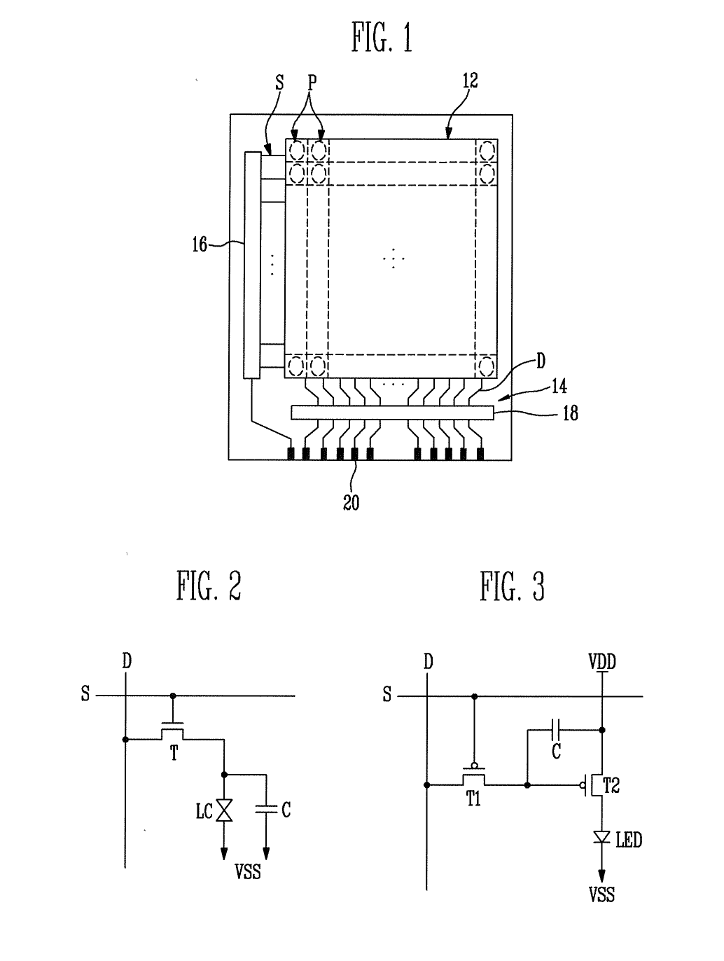

FIG. 1 is a schematic plan view illustrating a flat panel display (FPD) according to an embodiment of the present invention.

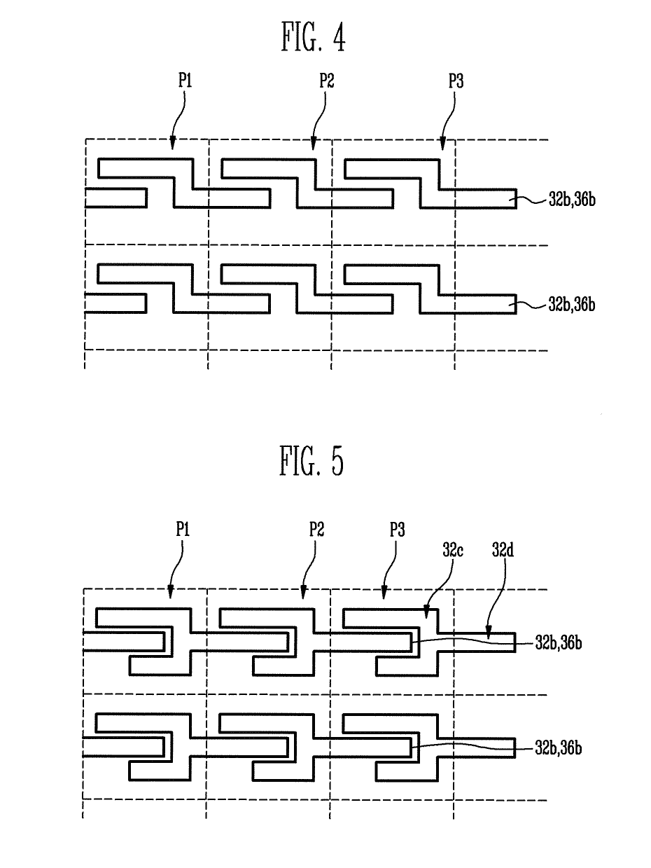

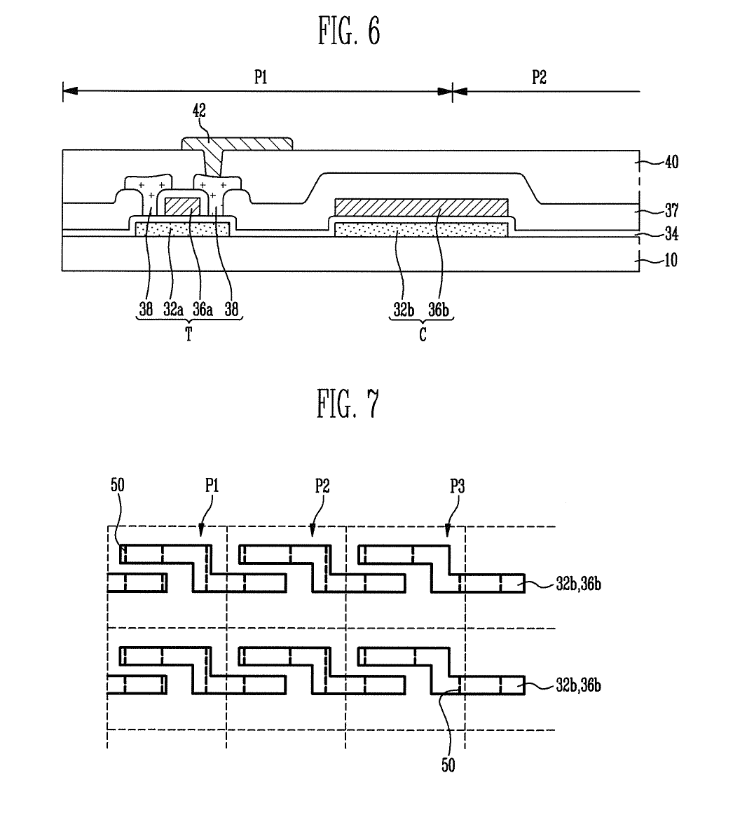

A substrate 10 (see FIG. 6) is defined by a pixel region 12, in which a plurality of pixel units P are arranged, and a non-pixel region 14 around the pixel region 12.

The plurality of pixel units P are arranged in columns and rows of the pixel region 12 of the substrate 10. The plurality of pixel units P may be coupled in a matrix to a plurality of scan lines S arranged in a row, and to a plurality of data lines D arranged in a column. For example, the red, green, and blue pixel units P are sequentially and repeatedly arranged in a row, and may be continuously arranged in a column. In addition, the plurality of pixel units P may include white pixel units.

Each of the pixel units P includes a pixel (e.g., a display element or a light emitting element, such as an OLED) and a pixel circuit for driving the pixel. The pixel circuit includes a thin film transistor (TFT) for driving the pixel and a capacitor coupled to the TFT to maintain a signal.

A scan driver 16 coupled to the scan lines S extended from the pixel region 12, a data driver 18 coupled to the data lines D extended from the pixel region 12, and a plurality of pads 20 to which external signals are input, are arranged in the non-pixel region 14 of the substrate 10. The scan driver 16 and the data driver 18 are coupled to the pads 20 through wiring lines and convert the signals provided from the outside through the pads 20 into scan signals and data signals to selectively drive the pixel units P.

FIGS. 2 and 3 are circuit diagrams illustrating embodiments of the pixel unit P of FIG. 1.

Referring to FIG. 2, a pixel unit P according to an embodiment of the present invention includes a pixel formed of a liquid crystal (LC) cell LC and a pixel circuit that includes a thin film transistor (TFT) T, which is coupled between a respective one of the plurality of scan lines S and a respective one of the plurality of data lines D, and a capacitor C, which is coupled between the TFT T and a common voltage Vss. The LC cell LC is coupled to the capacitor C in parallel.

Referring to FIG. 3, a pixel unit P according to another embodiment of the present invention includes a pixel formed of an organic light emitting diode (OLED) LED and a pixel circuit that includes a first TFT T1, which is coupled between a respective one of the plurality of scan lines S and a respective one of the plurality of data lines D, a second TFT T2, which is coupled to a power source voltage V_{DD} and is driven by an output signal of the first TFT T1, and a capacitor C coupled between a gate electrode and a drain electrode of the second TFT T2. The OLED LED is coupled between a source electrode of the second TFT T2 and the common voltage Vss, and may emit, for example, red, green, blue, or white light.

The OLED LED includes an anode electrode, a cathode electrode, and an organic thin film formed between the anode electrode and the cathode electrode. The organic thin film has a structure in which a hole transport layer, an organic emission layer, and an electron transport layer are laminated, and may further include a hole injecting layer and an electron injecting layer.

The common voltage Vss has a lower electric potential than the power source voltage V_{DD}, and the drain electrode and the source electrode may be used as a source electrode and a drain electrode, respectively.

FIGS. 4 and 5 are layout diagrams illustrating embodiments of the pixel unit P of the embodiments shown in FIG. 1.

Each of a plurality of pixel units P1, P2, P3, . . . includes a pixel and a pixel circuit for driving the pixel. The pixel circuit includes a TFT T, which is for controlling the operation of the pixel, and a capacitor C for maintaining a signal. However, for convenience sake, only the capacitor C is schematically illustrated.

Referring to FIG. 4, the capacitor C according to an embodiment of the present invention includes two electrodes 32b and 36b arranged to overlap each other. The two electrodes 32b and 36b may be arranged so that at least parts of the two electrodes 32b and 36b overlap each other. The electrodes 32b and 36b of the capacitor C formed in a pixel unit (for example, the first pixel unit P1) are extended to another adjacent pixel unit (for example, the second pixel unit P2). The electrodes 32b and 36b of the capacitor C of the first pixel unit P1 extended to the second pixel unit P2 may overlap the electrodes 32b and 36b of the capacitor C formed in the second pixel unit P2. That is, at least parts of the electrodes 32b and 36b of the capacitor C of the first pixel unit P1 may run parallel with at least parts of the electrodes 32b and 36b of the capacitor C of the second pixel unit P2. The electrodes 32b and 36b include a lower electrode and an upper electrode. At least one electrode is formed of a polysilicon layer. The electrodes 32b and 36b may be formed to be curved to effectively secure capacitance in a limited area.

Referring to FIG. 5, a capacitor C according to another embodiment of the present invention includes two electrodes 32b and 36b arranged to overlap each other. The two electrodes 32b and 36b may be arranged so that at least parts of the two electrodes 32b and 36b overlap each other. The electrodes 32b and 36b of the capacitor C formed in a pixel unit (for example, the first pixel unit P1) are extended to another adjacent pixel unit (for example, the second pixel unit P2). The electrodes 32b and 36b of the capacitor C of the first pixel unit P1 extended to the second pixel unit P2 may overlap the electrodes 32b and 36b of the capacitor C formed in the second pixel unit P2. That is, at least parts of the electrodes 32b and 36b of the capacitor C of the first pixel unit P1 may run parallel with at least parts of the electrodes 32b and 36b of the capacitor C of the second pixel unit P2.

The electrodes 32b and 36b of the capacitor C include first parts 32c, which include “ [symbol] ” shaped (e.g., u-shaped or c-shaped) concave parts, and second parts 32d, which protrude from the first parts 32c. The first and second parts 32c and 32d may overlap each other so that the second parts 32d of the first pixel unit P1 are inserted into the concave parts of the first parts 32c of the second pixel unit P2, and so that the second parts 32d of the second pixel unit P2 are inserted into the concave parts of the first parts 32c of the third pixel unit P3. That is, the second parts 32d of the first pixel unit P1 are inserted into the concave parts of the first parts 32c of the second pixel unit P2 to run parallel, and the second parts 32d of the second pixel unit P2 are inserted into the concave parts of the first parts 32c of the third pixel unit P3 to run parallel. The electrodes 32b and 36b include a lower electrode and an upper electrode, with at least one electrode being formed of a polysilicon layer.

In each of FIGS. 4 and 5, the shapes of the two electrodes 32b and 36b of the capacitor C are respectively the same. However, one electrode 32b or 36b (for example, the lower electrode or the upper electrode) may have the shape described in reference to the embodiments mentioned above, and the other electrode 36b or 32b (of the upper electrode or the lower electrode) may be a common electrode of a plurality of capacitors C arranged in a row or in a column and may be line shaped or plate shaped.

FIG. 6 is a sectional view illustrating an embodiment of the pixel unit P of FIG. 1.

Referring to FIGS. 4 and 5, the substrate 10 is defined by the plurality of pixel units P1, P2, P3, . . . , each of which includes a pixel, as well as a TFT T and a capacitor C as a pixel circuit for driving the pixel. However, for convenience sake, only the first and second pixel units P1 and P2 are schematically illustrated.

Referring to FIG. 6, the TFT T and the pixel and the capacitor C coupled to the TFT T are formed on the substrate 10 of the first pixel unit P1.

The TFT T includes an activation layer 32a formed on the substrate 10 to provide a source and drain region and a channel region, a gate electrode 36a formed on the activation layer 32a of the channel region and insulated by an insulating layer 34, and source and drain electrodes 38 coupled to the activation layer 32a of the source and drain region.

The pixel includes a pixel electrode 42, which is formed on a planarizing layer 40 formed in an upper part including the TFT T, and which is coupled to the source or drain electrode 38 of the TFT T through a via hole formed in the planarizing layer 40.

The LC cell LC of the embodiment illustrated in FIG. 2 includes a pixel electrode 42, a common electrode (not shown) facing the pixel electrode 42, and liquid crystal (LC) between the pixel electrode 42 and the common electrode. The OLED of the embodiment illustrated in FIG. 3 may include the pixel electrode (the anode electrode) 42, the common electrode (the cathode electrode) (not shown) facing the pixel electrode 42, and an organic thin film (not shown) between the pixel electrode 42 and the common electrode.

The capacitor C includes a lower electrode 32b, a dielectric layer 34, and an upper electrode 36b formed on the substrate 10 adjacent to the TFT T in a lamination structure. The lower electrode 32b of the capacitor C may be formed at the same plane (e.g., on the substrate 10) as the activation layer 32a of the TFT T, and may be formed of the same material, for example, a polysilicon layer. The dielectric layer 34 of the capacitor C may be formed of the gate insulating layer 34 of the TFT T. In addition, the upper electrode 36b of the capacitor C may be formed at the same plane (e.g., on the gate insulating layer 34) as the gate electrode 36a of the TFT T, and may be formed of the same material, for example, a polysilicon layer or a metal layer.

Interlayer insulating layer 37 is for insulating the gate electrode 36a and the source and drain electrodes 38 of the TFT T from each other.

As illustrated in FIG. 6, the electrodes 32b and 36b of the capacitor C formed in the first pixel unit P1 are extended to the adjacent second pixel unit P2. Although not shown in FIG. 6, the electrodes 32b and 36b of the capacitor C formed in the second pixel unit P2 are extended to the adjacent third pixel unit p3.

According to the present embodiment of the present invention, at least one of the lower electrode 32b and the upper electrode 36b of the capacitor C is formed of a polysilicon layer, and the polysilicon layer may be crystallized by a laser beam. A case in which the lower electrode 32b of the capacitor C is formed of the polysilicon layer will be described.

After forming an amorphous silicon layer on the substrate 10, the amorphous silicon layer is crystallized to be changed into the polysilicon layer. The crystallized polysilicon layer is patterned to form the lower electrode 32b of the capacitor C and the activation layer 32a of the TFT T. Crystallization for changing amorphous silicon into single crystalline or polycrystalline silicon grains to improve carrier mobility may be performed by eximer laser annealing and sequential lateral solidification. In the crystallization process, since a bar shaped laser beam moves in one direction, protrusions are formed on a grain boundary. The protrusions may be vertical band shaped in the one direction.

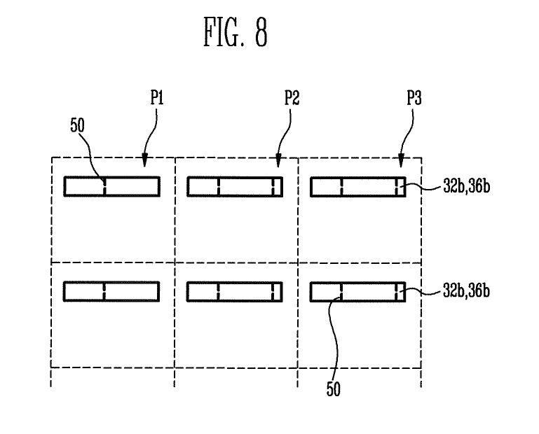

FIG. 7 is a plan view illustrating an electrode of a capacitor with protrusions formed.

Referring to FIG. 7, band shaped protrusions 50 are formed on the surfaces of the electrodes 32b and 36b of the capacitor C at regular intervals. In FIG. 7, a bar shaped laser beam moves from the first pixel unit P1 to the third pixel unit P3, or from the third pixel unit P3 to the first pixel unit P1. In this case, the protrusions 50 are formed in a direction vertical to the direction in which the laser beam moves.

According to the present embodiment of the present invention, a uniform number of protrusions 50 are arranged in the electrodes 32b and 36b of the capacitor C. For example, four protrusions 50 may be arranged (e.g., may be arranged at predetermined intervals). In addition, the protrusions 50 arranged in the electrodes 32b and 36b of the capacitor C of the first pixel unit P1 extended to the second pixel unit P2 may coincide in one direction with (e.g., align with) the electrodes 32b and 36b of the capacitor C formed in the second pixel unit P2.

When the electrodes 32b and 36b of the capacitor C are arranged only in the pixel units P1, P2, P3, . . . , as illustrated in FIG. 8, the protrusions 50 may be formed. In the present embodiment, for example, one protrusion 50 is formed in the electrodes 32b and 36b of the capacitor C of the first pixel unit P1. Alternatively, two protrusions 50 may be formed in the electrodes 32b and 36b of the capacitor C of the second and third pixel units P2 and P3.

As described above, when the number of protrusions 50 formed in the electrodes 32b and 36b is non-uniform, since the distance between the lower electrode 32b and the upper electrode 36b is non-uniform by capacitor C, the capacitances of the capacitors C are resultantly non-uniform. When the capacitances of the capacitors C are non-uniform, since current that drives a pixel varies by pixel circuit, a spot phenomenon may be generated due to a difference in brightness.

However, according to the present embodiment of the present invention, since the uniform number of protrusions 50 are arranged in the electrodes 32b and 36b of the capacitor C of each of the pixel units P1, P2, P3, . . . , the capacitances of all of the capacitors C are almost the same. Therefore, the above problem is not generated.

According to embodiments of the present invention, the number of protrusions 50 formed in the electrodes 32b and 36b of the capacitors C might not be the same, but may be determined in a range where the distances between the lower electrodes 32b and the upper electrodes 36b may be equalized.

While embodiments of the present invention has been described in connection with certain exemplary embodiments, it is to be understood that the invention is not limited to the disclosed embodiments, but, on the contrary, is intended to cover various modifications and equivalent arrangements included within the spirit and scope of the appended claims, and equivalents thereof.

What is claimed is:

1. A flat panel display (FPD) comprising:
a substrate;
a plurality of pixel units on the substrate, each of the pixel units comprising:
a display element;
a thin film transistor (TFT) electrically coupled to the display element; and
a capacitor electrically coupled to the TFT and comprising electrodes,
wherein the electrodes of the capacitor of a first pixel unit of the pixel units are extended to an adjacent pixel unit of the pixel units.

2. The FPD as claimed in claim 1, wherein the electrodes of the capacitor of the first pixel unit overlap electrodes of the capacitor of the adjacent pixel unit.

3. The FPD as claimed in claim 2, wherein the electrodes of the capacitor comprise:
a concave first part; and
a second part extending from the first part, and
wherein the second part of the capacitor of the first pixel unit is at least partially surrounded by the first part of the capacitor of the adjacent pixel unit.

4. The FPD as claimed in claim 1, wherein the electrodes of the capacitor comprise a lower electrode and an upper electrode, and
wherein at least one of the lower electrode or the upper electrode comprises a polysilicon layer.

5. The FPD as claimed in claim 4, wherein protrusions in the electrodes of the capacitor of the first pixel unit align with protrusions in the electrodes of the capacitor of the adjacent pixel unit.

6. The FPD as claimed in claim 1, wherein the TFT comprises an activation layer at a same plane as one of the lower electrode and the upper electrode of the capacitor.

7. The FPD as claimed in claim 4, wherein the polysilicon layer is crystallized by a laser beam.

8. The FPD as claimed in claim 7, further comprising protrusions arranged at the polysilicon layer.

9. The FPD as claimed in claim 8, wherein the protrusions comprise protrusions in the electrodes of the capacitor, and wherein the protrusions in the electrodes of the capacitor of the first pixel unit align with the protrusions in the electrodes of the capacitor of the adjacent pixel unit.

10. The FPD as claimed in claim 1, wherein the display element comprises a liquid crystal (LC) cell.

11. The FPD as claimed in claim 1, wherein the display element comprises an organic light emitting diode (OLED).

12. The FPD as claimed in claim 1, wherein the electrodes of the capacitor comprise a lower electrode and an upper electrode, and
wherein at least one of the lower electrode or the upper electrode of the first pixel unit is extended to the adjacent pixel unit.

13. The FPD as claimed in claim 12, wherein at least one of the lower electrode or the upper electrode comprises a polysilicon layer.
